(19) United States
(12) Patent Application Publication
(10) Pub. No.: US 2026/0082630 A1
(43) Pub. Date: Mar. 19, 2026

(54) SELF ALIGNED BACKSIDE CHANNEL REMOVAL

(71) Applicant: International Business Machines Corporation, Armonk, NY (US)

(72) Inventors: Min Gyu Sung, Latham, NY (US); Tao Li, Slingerlands, NY (US); Ruilong Xie, Niskayuna, NY (US); Nicolas Jean Loubet, GUILDERLAND, NY (US)

(21) Appl. No.: 18/885,802

(22) Filed: Sep. 16, 2024

(51) Int. Cl. H01L 29/417; H01L 21/8238; H01L 27/092; H01L 29/06; H01L 29/08; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121; H10D 62/151; H10D 84/0186; H10D 84/038; H10D 84/85

(57) ABSTRACT

A semiconductor structure including a first stack of semiconducting layers in a first region, a second stack of semiconducting layers in a second region, where the second stack of semiconducting layers in the second region has at least one fewer layer than the first stack of semiconducting layers in the first region, a backside channel plug directly beneath the first stack of semiconducting layers in the first region, and a gate cut contact structure extending between a backside contact structure and a source drain contact on a frontside.

### BACKGROUND

The present invention generally relates to semiconductor structures, and more particularly to transistor structures having stacks of semiconducting layers with different number of channels.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet FET includes a plurality of stacked nanosheets extending between a pair of source drain epitaxial regions. The device may be a gate-all-around device or transistor in which the gate surrounds a portion of the nanosheet channel. A nanosheet device contains one or more layers of semiconductor channel material portions having a vertical thickness that is substantially less than its width.

### SUMMARY

According to an embodiment of the present invention, a semiconductor structure is provided. The semiconductor structure may include a first stack of semiconducting layers in a first region, a second stack of semiconducting layers in a second region, where the second stack of semiconducting layers in the second region has at least one fewer layer than the first stack of semiconducting layers in the first region, a backside channel plug directly beneath the first stack of semiconducting layers in the first region, and a gate cut contact structure extending between a backside contact structure and a source drain contact on a frontside.

According to another embodiment of the present invention, a semiconductor structure is provided. The semiconductor structure may include a first stack of semiconducting layers in a first region, a second stack of semiconducting layers in a second region, where the second stack of semiconducting layers in the second region has at least one fewer layer than the first stack of semiconducting layers in the first region, a backside channel plug directly beneath the first stack of semiconducting layers in the first region, and gate cut contact structures extending between backside contact structures and source drain contacts on a frontside, where one of the backside source drain contact structures in the second region is surrounded by a dielectric trench liner and a dielectric fill.

According to another embodiment of the present invention, a semiconductor structure is provided. The semiconductor structure may include a first gate surrounding at least one layer of a first stack of semiconducting layers in a first region, a second gate surrounding at least one layer of a second stack of semiconducting layers in a second region, where the second stack of semiconducting layers in the second region has at least one fewer layer than the first stack of semiconducting layers in the first region, a backside channel plug directly beneath the first stack of semiconducting layers in the first region, where a top portion of the backside channel plug is surrounded on at least two sides by the second gate in the second region, and a gate cut contact structure extending between a backside contact structure and a source drain contact on a frontside.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIGS. 2, 3, and 4 are cross-sectional views of the semiconductor structure during an intermediate step of a method of fabricating a transistor structure according to an exemplary embodiment;

FIGS. 5, 6, and 7 are cross-sectional views of the semiconductor structure after flipping the assembly and recessing the substrate according to an exemplary embodiment;

FIGS. 8, 9, and 10 are cross-sectional views of the semiconductor structure after removing and recessing remaining portions of the substrate according to an exemplary embodiment;

FIGS. 11, 12, and 13 are cross-sectional views of the semiconductor structure after forming a first mask and removing portions of the top semiconductor layer to form backside openings according to an exemplary embodiment;

FIGS. 14, 15, and 16 are cross-sectional views of the semiconductor structure after removing portions of the gate and a bottommost channel region according to an exemplary embodiment;

FIGS. 17, 18, and 19 are cross-sectional views of the semiconductor structure after forming backside channel plugs and a backside dielectric layer according to an exemplary embodiment;

FIGS. 20, 21, and 22 are cross-sectional views of the semiconductor structure after forming a hard mask layer, a second mask, and first backside contact trenches according to an exemplary embodiment;

FIGS. 23, 24, and 25 are cross-sectional views of the semiconductor structure after forming a dielectric trench liner a dielectric fill according to an exemplary embodiment;

FIGS. 26, 27, and 28 are cross-sectional views of the semiconductor structure after forming a third mask and second backside contact trenches according to an exemplary embodiment; and

FIGS. 29, 30, 31, 32, 33, and 34 are cross-sectional views of the semiconductor structure after forming backside contact structures 166 and backside wiring layers according to an exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, including gate-all-around transistor devices and nanosheet transistor devices, have known advantages over conventional transistor structures in terms of density, performance, power consumption, and integration. However, fabricating devices to suit different design constraints or requirements presents unique challenges. More specifically, for example, continued scaling of device dimensions to conserve power and optimize performance have known limitations.

For example, scaling RX width is a productive way to control or reduce power consumption; however, edge capacitance limits any benefit achieved by scaling RX width.

Furthermore, setting aside any edge capacitance concerns, current lithography and patterning constraints limit RX width variations within a circuit row. Therefore, there is a need for other solutions to conserve power and optimize performance to suit different design constraints.

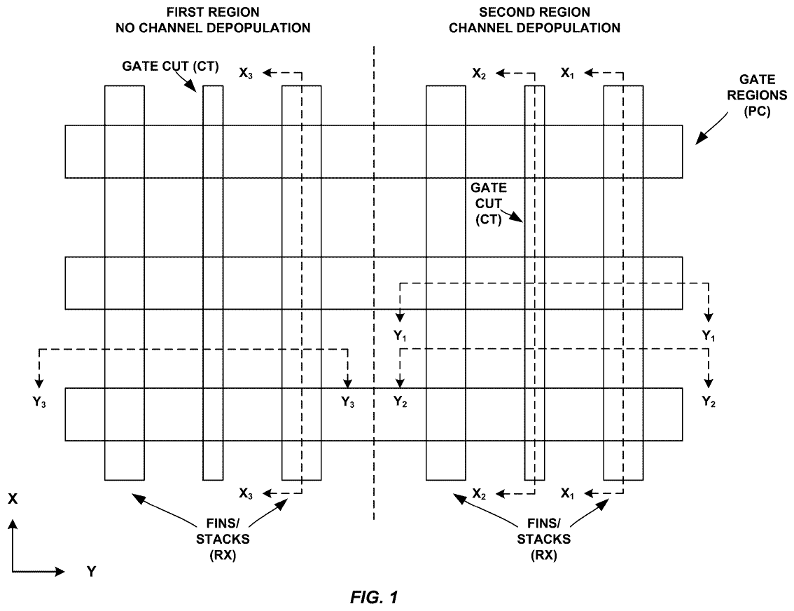

The present invention generally relates to semiconductor structures, and more particularly to transistor structures having stacks of semiconducting layers with different number of channels. More specifically, the transistor structures and associated method disclosed herein enable a novel solution for providing nanosheet stacks of semiconducting layers having one or more channels removed. Removing one or more channels from nanosheet stacks can be referred to as “channel depopulation”. Exemplary embodiments of transistor structures having stacks of semiconducting layers with different number of channels are described in detail below by referring to the accompanying drawings in FIGS. 1 to 34. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

For purposes of the present description a portion of the structure is designated as a first region having no channels removed (ie no channel depopulation), another portion of the structure is designated as a second region having one or more channels removed (ie channel depopulation).

The generic structure illustrated in FIG. 1 shows multiple fins/stacks and multiple gate regions situated perpendicular to one another. FIGS. 1-34 represent cross section views oriented as indicated in FIG. 1

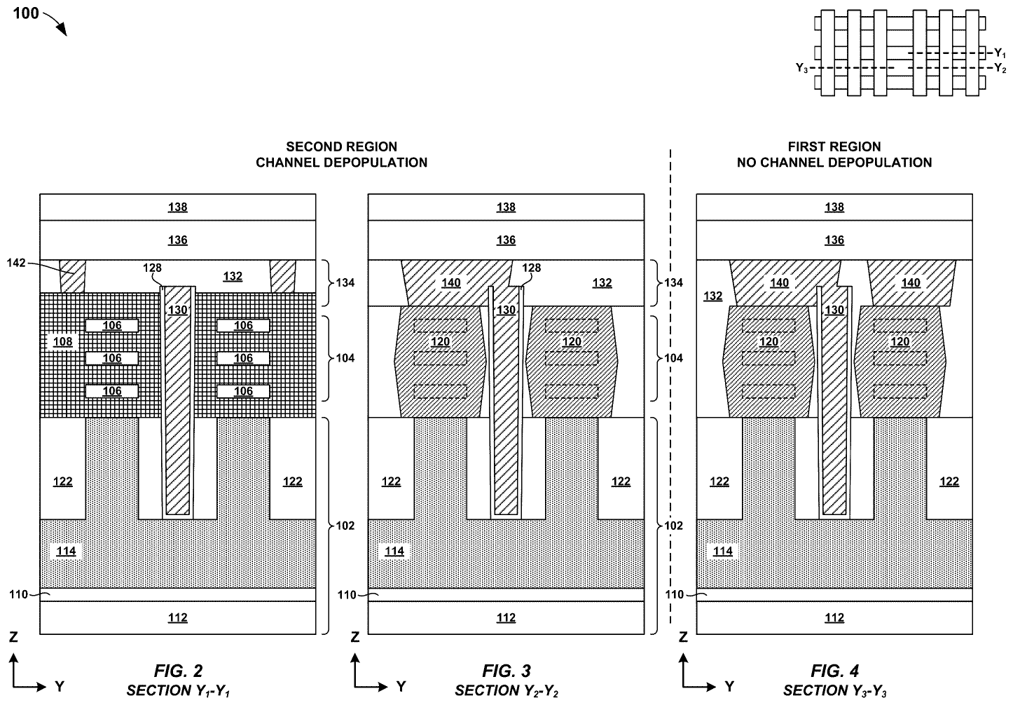

Referring now to FIGS. 2, 3, and 4, a structure 100 is shown during an intermediate step of a method of fabricating a transistor structure according to an embodiment of the invention. FIG. 2 depicts a cross-sectional view of the structure 100 taken along line Y₁-Y₁, FIG. 3 depicts a cross-sectional view of the structure 100 taken along line Y₂-Y₂, and FIG. 4 depicts a cross-sectional view of the structure 100 taken along line Y₃-Y₃.

The structure 100 illustrated in FIGS. 2-4 includes an array of transistors formed on a substrate 102 in accordance with known techniques. As illustrated, the array of transistors includes stacks of semiconducting layers 104 (hereinafter nanosheet stacks 104). As disclosed herein, and according to embodiments of the present disclosure, the semiconducting layers further include fork sheets, nanosheets, nanowires, 2D TMD channels, other equivalent layers. Each nanosheet stack 104 includes a plurality of channel regions 106 surrounded by a gate 108. For purposes of orientation, the substrate 102 is herein referred to as being on a “backside” of the structure 100 and the array of transistors are herein referred to as being on a “frontside” of the structure 100. Further, certain features may be described herein as having a relative position with respect to the frontside or backside of the structure 100.

The substrate 102 may be a layered semiconductor such as a silicon-on-insulator or SiGe-on-insulator, where an etch stop layer 110 separates a base substrate 112 from a top semiconductor layer 114. Unlike conventional layered semiconductor substrates, the etch stop layer 110 of the substrate 102 may include any material which affects the desired etch selectivity during subsequent processing. For example, the etch stop layer 110 may be a conventional buried oxide layer, or it may be a silicon germanium layer with a specific germanium concentration. In practice, the etch stop layer 110 will function as an etch stop layer and can be composed of any material which supports that function.

In the present embodiment, both the base substrate 112 and the top semiconductor layer 114 may be any bulk substrate made from any of several known semiconductor materials such as, for example, silicon, germanium, silicon-germanium alloy, and compound (e.g. III-V and II-VI) semiconductor materials. For example, both the base substrate 112 and the top semiconductor layer 114 may be made from silicon. Additionally, both the etch stop layer 110 and the base substrate 112 are sacrificial and will not remain in the final structure. As such, thickness of the top semiconductor layer 114, and similarly the position of the etch stop layer 110, approximately denote a relative position of subsequently formed backside features, such as, backside wiring layers or a backside power delivery network.

The structure 100 further includes source drain regions 120 generally arranged between adjacent nanosheet stacks 104, and shallow trench isolation regions 122 (hereinafter “STI regions 122”), as illustrated.

The source drain regions 120 are formed between adjacent nanosheet stacks 104 according to known techniques. Specifically, the source drain regions 120 directly contact exposed ends of the channel regions 106. More specifically, the source drain regions 120 may be epitaxially grown from the exposed ends of the channel regions 106 according to known techniques.

The STI regions 122 extend partially into the substrate 102 below the array of nanosheet transistors. In general, the STI regions 122 may each include an isolation liner and an isolation fill. For example, the isolation liner is SiN, SiON, or SiOCN, and the isolation fill is silicon oxide (SiO) or silicon nitride (SiN).

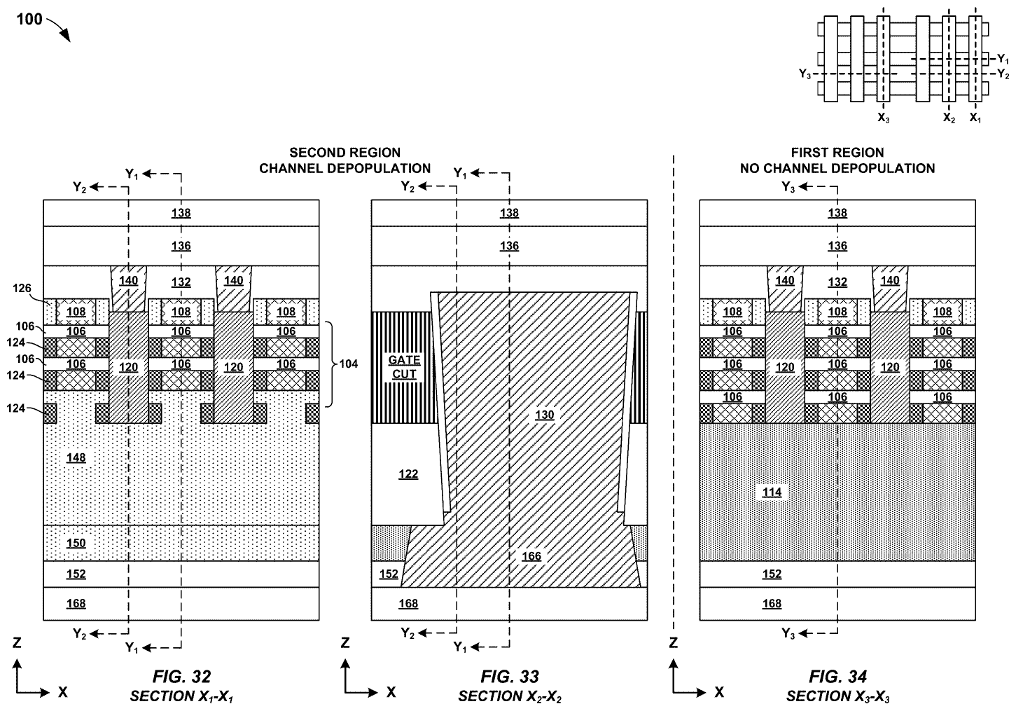

The structure 100 further includes inner spacers 124 (FIGS. 32-34), gate spacers 126 (FIGS. 32-34), and gate cut contact structures.

The inner spacers 124 are disposed between alternate channel regions 106, and laterally separate the gate 108 from the source drain regions 120, as illustrated. The inner spacers 124 define the channel length and provide necessary electrical insulation between the gate 108 and the source drain regions 120.

The gate spacers 126 are added to define the source drain regions, and ultimately electrically insulate the gate 108 from subsequently formed structures, such as, for example, source drain contact structures. The gate spacers 126 are critical for electrically insulating the gate 108 from the source drain regions 120 or subsequently formed contact structures. In at least one embodiment, the gate spacers 126 include silicon nitride, silicon boron nitride, silicon carbon nitride, silicon boron carbon nitride, or other known equivalents.

The gate cut contact structures are conductive features which extend through the device region, or front-end-of-line, through the STI regions 122, and provide a conductive path between the frontside and the backside of the structure 100 as referenced herein. The function and/or purpose of such a conductive path will become apparent in subsequent description. Typically, the gate cut contact structures each include a contact liner 128 and a contact fill 130 as is known and according to an embodiment of the invention. In an embodiment, the contact liners are silicon nitride; however, other suitable dielectric liner materials may also be used. Meanwhile, according to disclose embodiments, the contact fill 130 is copper or tungsten; however, other suitable conductive materials may also be used.

According to the embodiments disclosed herein, the gate cut contact structures may also function to isolate, or separate, individual gate regions, as illustrated. For example, each individual gate region may include a single nanosheet stack 104 or multiple nanosheet stacks 104 having a common gate 108. Additionally, the different nanosheet stacks 104 separated by the gate cut contact structures may be N-type, P-type, or any combination thereof. Finally, the gate cut contact structures can be positioned anywhere according to a desired design and are not necessarily limited to the positions and configurations depicted and described herein.

The structure 100 further includes a dielectric layer 132, a middle-of-line 134, a back-end-of-line 136, a carrier wafer 138.

The dielectric layer 132 is directly above and surrounding the source drain regions 120. The dielectric layer 132 is composed of any suitable interlayer dielectric material, such as, for example, oxides such as silicon oxide (SiOₓ), nitrides such as silicon nitride (SiₓN_{y}), and/or low-κ materials such as SiCOH or SiBCN. In another embodiment, is composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In yet another embodiment, a self-planarizing material such as a spin-on glass (SOG) or a spin-on low-k dielectric material such as SiLK™ can be used to form the dielectric layer 132. Using a self-planarizing dielectric material as the dielectric layer 132 can avoid the need to perform a subsequent planarizing step. After formation, top surfaces of the dielectric layer 132 are typically made flush, or substantially flush, with top surfaces of the gate 108 and the gate spacers 126 by chemical mechanical polishing techniques.

The middle-of-line 134 includes source drain contacts 140 and gate contacts 142 which may be generally referred to as middle-of-line contacts. The source drain contacts 140 and the gate contacts 142 are formed according to known techniques. The back-end-of-line 136 may include vias and metal lines which may be generally referred to as back-end-of-line interconnects. The vias and the metal lines are formed according to known techniques. Finally, the carrier wafer 138 is secured to a top of the structure 100 according to an embodiment of the invention. The carrier wafer 138 is attached, or removably secured, to the back-end-of-line 136. In general, and not depicted, the carrier wafer 138 may be thicker than the other layers. Temporarily bonding the structure 100 to a thicker carrier provides improved handling and additional support for backside processing of thin wafers. After backside processing described below, the structure 100 may be de-bonded, or removed, from the carrier wafer 138 according to known techniques.

Although only a limited number of components, devices, or structures are shown, embodiments of the present invention shall not be limited by any quantity otherwise illustrated or discussed herein.

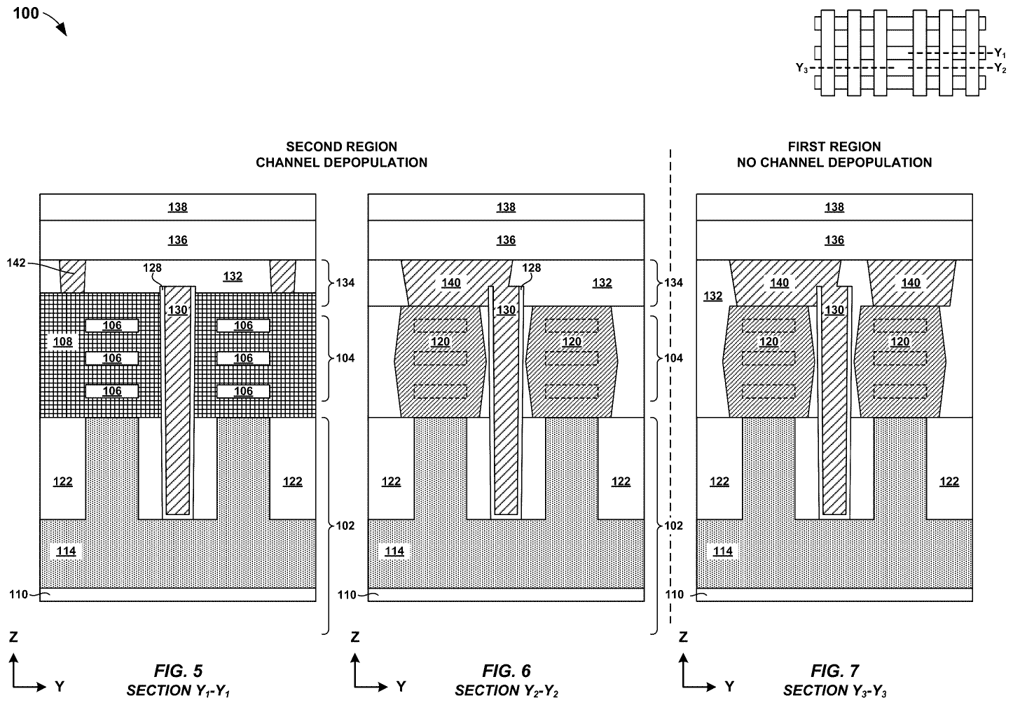

Referring now to FIGS. 5, 6, and 7, the structure 100 is shown after flipping the assembly and recessing the substrate 102 according to an embodiment of the invention. FIG. 5 depicts a cross-sectional view of the structure 100 taken along line Y₁-Y₁, FIG. 6 depicts a cross-sectional view of the structure 100 taken along line Y₂-Y₂, and FIG. 7 depicts a cross-sectional view of the structure 100 taken along line Y₃-Y₃.

First, the structure 100 is flipped 180 degrees to prepare for backside processing. In general, backside processing includes fabrication or processing of the structure 100 opposite the active device and wiring layers. Next, the substrate 102 is recessed according to known techniques. Specifically, the base substrate 112 is recessed or completely removed to expose the etch stop layer 110, as shown. It is noted, the orientation of the cross-sectional views referenced and illustrated hereafter will remain unchanged despite the actualities of flipping of the structure 100 for purposes of fabrication. As such, all references to “upper”, “lower”, “right”, “left”, “vertical”, “horizontal”, “top”, “bottom”, and derivatives thereof shall continue to relate to the disclosed structures and methods, as oriented in the drawing figures.

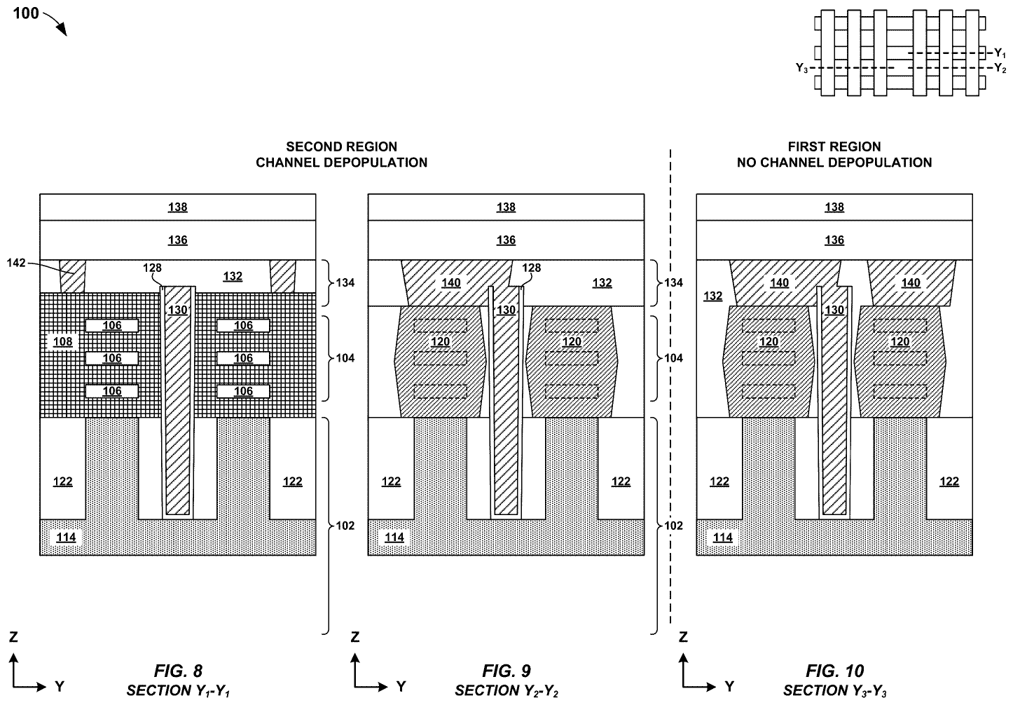

Referring now to FIGS. 8, 9, and 10, the structure 100 is shown after removing and recessing remaining portions of the substrate 102 according to an embodiment of the invention. FIG. 8 depicts a cross-sectional view of the structure 100 taken along line Y₁-Y₁, FIG. 9 depicts a cross-sectional view of the structure 100 taken along line Y₂-Y₂, and FIG. 10 depicts a cross-sectional view of the structure 100 taken along line Y₃-Y₃.

First, the etch stop layer 110 is selectively removed and the top semiconductor layer 114 is recessed according to known techniques. Specifically, the etch stop layer 110 is removed selective to the top semiconductor layer 114. After removing the etch stop layer 110, known chemical mechanical polishing may be used to recess the top semiconductor layer 114 from bottom surfaces of the structure 100. Critical to the disclosed embodiments, polishing must continue until a thickness of the top semiconductor layer 114, measured from bottoms of the STI, is a target thickness suitable for fabricating backside contact structures. If the top semiconductor layer 114 is not polished, it increases the difficult of backside processing. If the top semiconductor layer 114 is polished too much, it increases the risk any over etching during backside processing may create shorts. For example, polishing continues until a thickness of the top semiconductor layer 114, measured from bottoms of the STI, is approximately 50 nm.

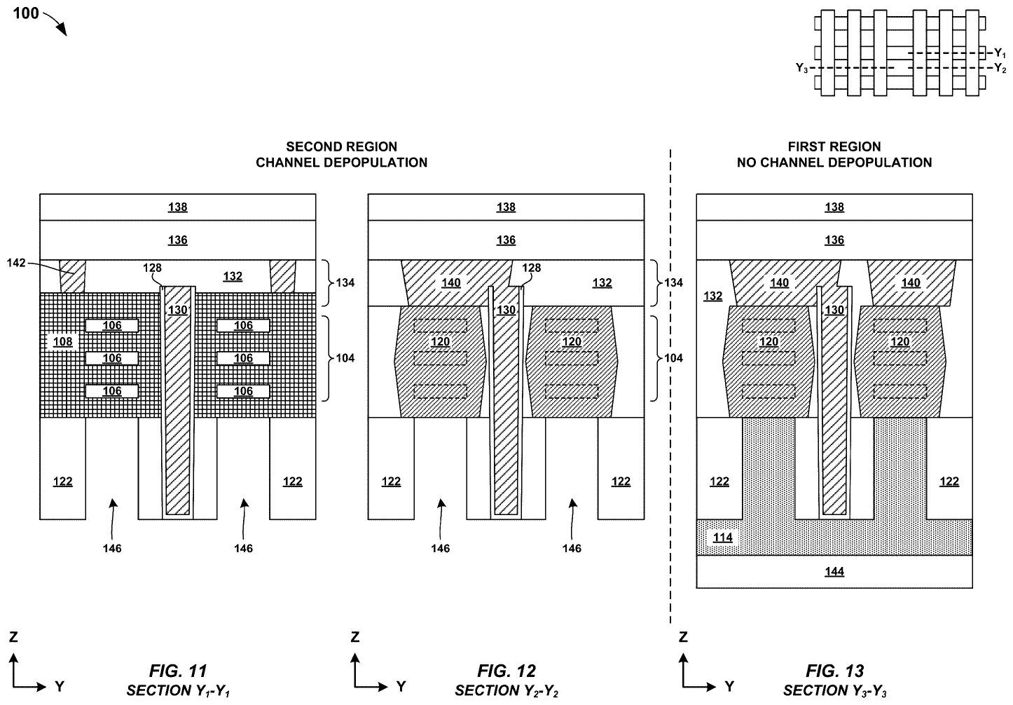

Referring now to FIGS. 11, 12, and 13, the structure 100 is shown after forming a first mask 144 and removing portions of the top semiconductor layer 114 to form backside openings 146 according to an embodiment of the invention. FIG. 11 depicts a cross-sectional view of the structure 100 taken along line Y₁-Y₁, FIG. 12 depicts a cross-sectional view of the structure 100 taken along line Y₂-Y₂, and FIG. 13 depicts a cross-sectional view of the structure 100 taken along line Y₃-Y₃.

The first mask 144 is deposited and subsequently patterned to expose certain backside portions of the structure 100 according to known techniques. The first mask 144 can be an organic planarization layer (OPL) or a layer of material that is capable of being planarized or etched by known techniques. In an embodiment, for example, the first mask 144 can be an amorphous carbon layer able to withstand subsequent processing temperatures. The first mask 144 can preferably have a thickness sufficient to cover existing structures. After depositing the first mask 144, a dry etching technique is applied to pattern the first mask 144 according to known techniques. The first mask 144 is patterned to expose backside surfaces in the second region (see FIGS. 11 and 12) and remains across backside surfaces of the first region (see FIG. 13). Specifically, after patterning the first mask 144, portions of the remaining top semiconductor layer 114 will be exposed in the second region and other portions of the remaining top semiconductor layer 114 will remain covered in the first region.

Next, the backside openings 146 are formed according to known techniques. Specifically, known etching techniques, such as reactive ion etching, are used to remove portions of the top semiconductor layer 114 selective to the STI regions 122, the source drain regions 120, the inner spacers 124, and the gate 108, as illustrated. Meanwhile, portions of the gate 108 are exposed in the second region (FIGS. 11 and 12) and portions of the top semiconductor layer 114 remain in the first region (see FIG. 13). It is noted, since semiconductor material is removed selective to the surrounding STI regions 122, the backside openings 146 will have a relatively rectangular profile, as opposed to a more common tapered profile resulting from patterning trenches in a single material layer.

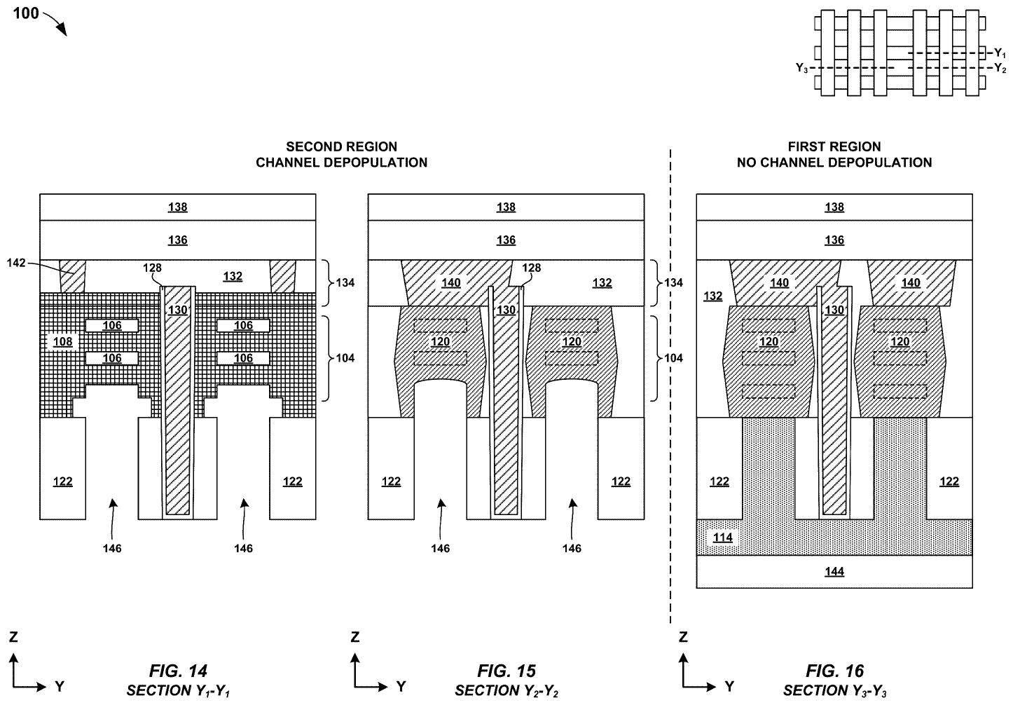

Referring now to FIGS. 14, 15, and 16, the structure 100 is shown after removing portions of the gate 108 and a bottommost channel region 106 according to an embodiment of the invention. FIG. 14 depicts a cross-sectional view of the structure 100 taken along line Y₁-Y₁, FIG. 15 depicts a cross-sectional view of the structure 100 taken along line Y₂-Y₂, and FIG. 16 depicts a cross-sectional view of the structure 100 taken along line Y₃-Y₃.

Portions of the gate 108 and the channel regions 106 are removed according to known techniques. For example, known directional or anisotropic etching techniques are used to enlarge or extend the backside openings 146 and sequentially remove portions of the gate 108 and the channel regions 106. More specifically, the gate 108 and the channel regions 106 are etched or recessed selective to the surrounding structures, specifically the inner spacers 124. In such cases, remaining portions of the bottommost inner spacers 124 function as a mask or template.

Unique to the embodiments disclosed herein, the backside openings 146 provides direct access from the backside and enables selective removal of portions of the gate 108 and/or portions of the channel regions 106. In the context of the present disclosure, and according to an embodiment, each channel region 106 illustrated in the figures, and described throughout, may include a top channel and a bottom channel. As such, the structures described and illustrated herein have a total of six channels; however, greater or fewer channel regions, and likewise channels, are explicitly contemplated. Further, one channel of the channel regions 106 is not functional, and this not present, unless surrounded by, or otherwise directly adjacent to, the gate 108. As such, removing a portion of the gate 108 directly adjacent to one of the channel regions 106 will effectively eliminate one channel from the total channel count. Therefore, selectively removing some combination of portions of the gate 108 and the channel regions 106 enable precise control of the number of channels in the exposed nanosheet stacks 104.

In an embodiment, for example, etching to extend the backside openings 146 continues until a first portion of the gate 108 is removed and the bottommost channel region 106 is exposed. As indicated above, doing so will effectively eliminate the bottom channel of the bottommost channel region 106 and reduce the total channel count by one.

In another embodiment, for example, etching to extend the backside openings 146 continues until the first portion of the gate 108 and at least a portion of the bottommost channel region 106 are removed. In such cases, the total channel count of the exposed nanosheet stack 104 would be reduced by one.

In yet another embodiment, for example, etching to extend the backside openings 146 continues until the first portion of the gate 108 and the bottommost channel region 106 are removed, as illustrated. In such cases, the total channel count of the exposed nanosheet stack 104 would be reduced by two.

In yet another embodiment, for example, etching to extend the backside openings 146 continues until the first portion of the gate 108, the bottommost channel region 106, and a second portion of the gate 108 are removed. In such cases, the total channel count of the exposed nanosheet stack 104 would be reduced by three.

In yet another embodiment, for example, etching to extend the backside openings 146 continues until the multiple portions of the gate 108 and all of the channel regions 106 are removed. In such cases, the total channel count of the exposed nanosheet stack 104 would be reduced by six.

The ability to selectively, and strategically, remove individual channels from the exposed nanosheet stack 104 enables designs which optimize power performance by uniquely tuning each nanosheet stack 104 with an appropriate number of channel regions 106 to fit the needs and requirements of the design.

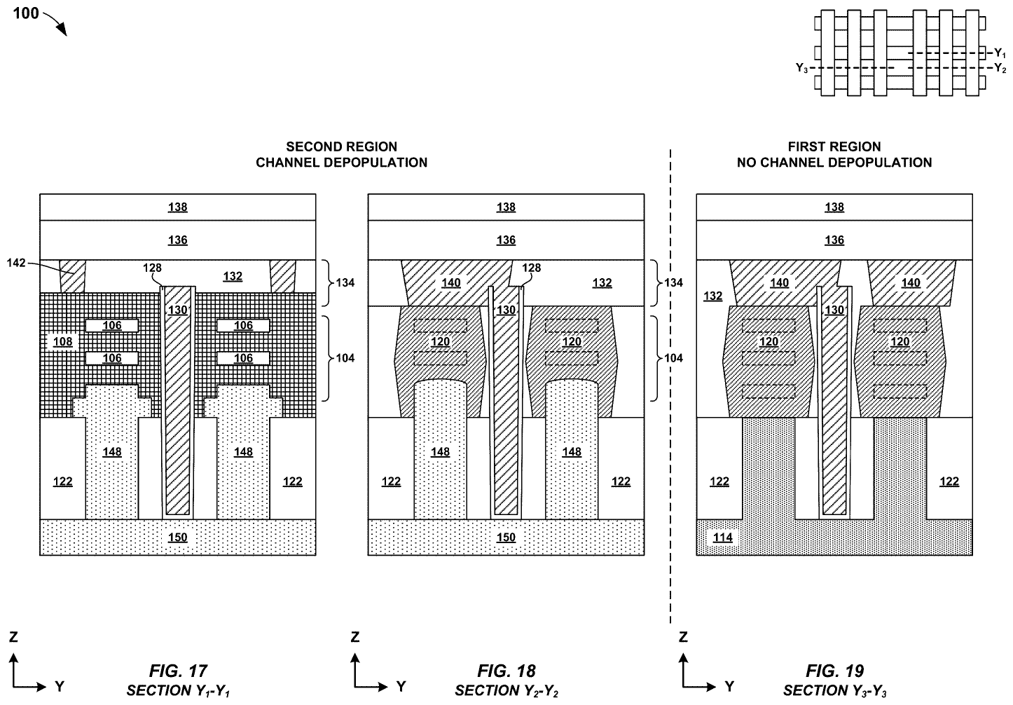

Referring now to FIGS. 17, 18, and 19, the structure 100 is shown after forming backside channel plugs 148 and a backside dielectric layer 150 according to an embodiment of the invention. FIG. 17 depicts a cross-sectional view of the structure 100 taken along line Y₁-Y₁, FIG. 18 depicts a cross-sectional view of the structure 100 taken along line Y₂-Y₂, and FIG. 19 depicts a cross-sectional view of the structure 100 taken along line Y₃-Y₃.

First, the first mask 144 is removed according to known techniques. In an embodiment, the first mask 144 is removed using known techniques, such as, for example, ashing.

Next, the backside channel plugs 148 and a backside dielectric layer 150 are formed according to known techniques. Specifically, a backside dielectric material is blanket deposited across the structure 100. The backside dielectric material fills the backside openings 146 and covers exposed backside surfaces of the structure 100. In all cases, the backside channel plugs 148 will directly contact bottommost surfaces of the gate 108, as illustrated. The backside channel plugs 148 are situated between and directly contact two adjacent STI regions 122. Said differently the backside channel plugs 148 are self-aligned to the STI regions 122. In all cases, topmost surfaces of the backside channel plugs 148 is entirely above topmost surfaces of the STI regions 122. Further, top sections of the backside channel plugs 148 will have a stepped profile and a portions extending laterally above the STI regions 122, as illustrated. (see FIG. 17).

After deposition, excess dielectric material can be polished using known techniques until bottommost surfaces of the backside dielectric material are flush, or substantially flush, with bottommost surfaces of the top semiconductor layer 114, as illustrated. In some cases, polishing may also recess the top semiconductor layer 114.

According to the disclosed embodiments, both the backside channel plugs 148 and a backside dielectric layer 150 are formed simultaneously with a single backside dielectric material. In such cases, the backside channel plugs 148 and a backside dielectric layer 150 may include any suitable low-k dielectric material, such as, for example, SiOx, SiN, SiOCN, or SiBCN.

In an alternative embodiment, the backside channel plugs 148 and a backside dielectric layer 150 are formed sequentially from at least two different dielectric materials. In such embodiments, the backside channel plugs 148 can be made from a hybrid stack of dielectrics. For example, one or more low-k dielectrics for the top portion nearest the gate 108, to minimize capacitance, and then one or more “harder” (i.e., higher-k) dielectrics for the bottommost portion to provide good etch selectivity during subsequent backside processing. In some embodiments, the backside channel plugs 148 are made from a compressive dielectric. Using a compressive dielectric would induce compressive strain in the channel regions 106 and either function to increase PFET current or decrease NFET current. In other embodiments, the backside channel plugs 148 are made from a tensile dielectric. Using a tensile dielectric would induce tensile strain in the channel regions 106 and either function to decrease PFET current or increase NFET current. In an embodiment, the backside channel plugs 148 are deposited using known deposition techniques, such as, for example, chemical vapor deposition (CVD), plasma enhanced CVD (PECVD), or atomic layer deposition (ALD).

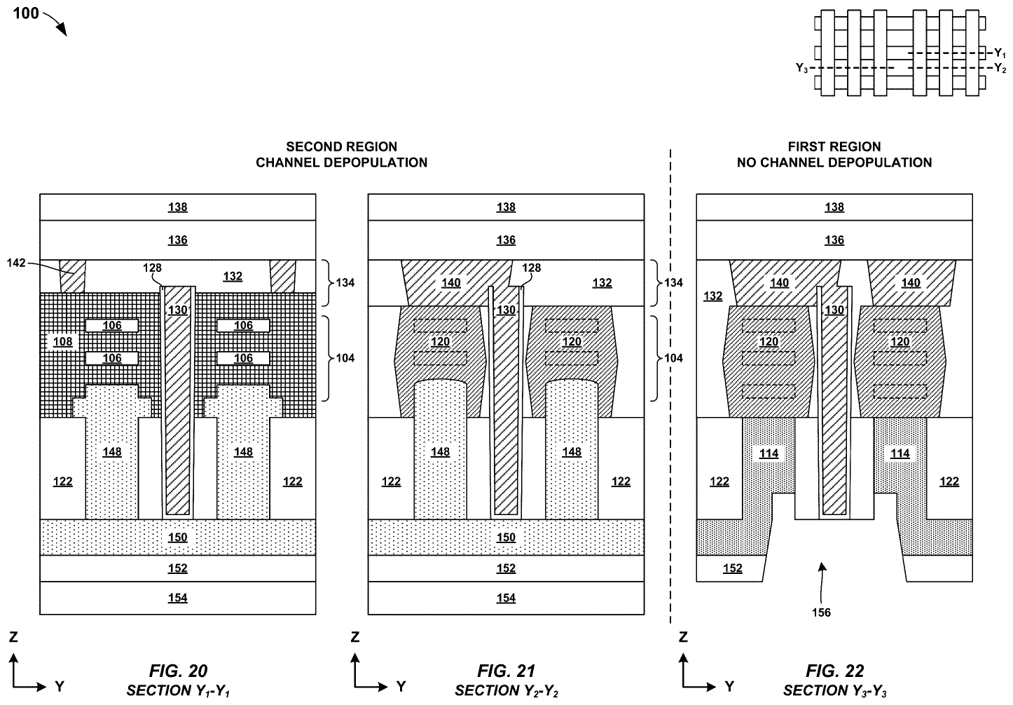

Referring now to FIGS. 20, 21, and 22, the structure 100 is shown after forming a hard mask layer 152, a second mask 154, and first backside contact trenches 156 according to an embodiment of the invention. FIG. 20 depicts a cross-sectional view of the structure 100 taken along line Y₁-Y₁, FIG. 21 depicts a cross-sectional view of the structure 100 taken along line Y₂-Y₂, and FIG. 22 depicts a cross-sectional view of the structure 100 taken along line Y₃-Y₃.

First, the hard mask layer 152is deposited according to known techniques. Specifically, the hard mask layer 152 is blanket deposited across the backside of the structure 100. In some embodiments, for example, the hard mask layer 152 may be composed of any dielectric which may be selectively etched relative to the surrounding materials. Typically, “harder”, more etch resistant, dielectrics are preferred, in order to avoid erosion during subsequent patterning. For example, suitable etch-resistance dielectrics may include SiN, AlOx, HfOx, or diamond-like carbon. According to embodiments of the present invention, the hard mask layer 152 provides etch selectivity and protection during subsequent backside processing. More specifically, the hard mask layer 152 must be made from a material which is etch selective to the top semiconductor layer 114.

Next, the second mask 154 is deposited and subsequently patterned to expose certain backside portions of the structure 100 according to known techniques. The second mask 154 can be an organic planarization layer (OPL) or a layer of material that is capable of being planarized or etched by known techniques. In an embodiment, for example, the second mask 154 can be an amorphous carbon layer able to withstand subsequent processing temperatures. The second mask 154 can preferably have a thickness sufficient to cover existing structures. After depositing the second mask 154, a dry etching technique is applied to pattern the second mask 154 according to known techniques. The second mask 154 is patterned to expose backside surfaces in the first region (see FIG. 22) and remains across backside surfaces of the second region (see FIGS. 20 and 21). Specifically, after patterning the second mask 154, portions of the hard mask layer 152 will be exposed in the first region and other portions of the hard mask layer 152 will remain covered in the second region.

Next, the hard mask layer 152, exposed in the first region, is patterned and the first backside contact trenches 156 are formed according to known techniques. Specifically, known techniques are used to pattern the exposed portions of the hard mask layer 152 in the first region according to known techniques. Next, according to an exemplary embodiment, RIE is used to transfer the hard mask pattern into the top semiconductor layer 114 to form the first backside contact trenches 156 according to known techniques and as illustrated. According to embodiments of the present invention, the first backside contact trenches 156 are generally aligned with one or more of the contact fill 130, as illustrated. According to the disclosed embodiments, portions of the top semiconductor layer 114 will be removed selective to the STI regions 122 and the contact liner 128. In a preferred embodiment, etching is designed to expose the contact liner 128.

In some embodiments, as illustrated, a lateral dimension of each of the first backside contact trenches 156 is greater than a lateral dimension of each of the STI regions 122. In such embodiments, sidewalls of the STI regions 122 are exposed during etching because the STI regions 122 and the top semiconductor layer 114 are made from two different materials having two different etch rates resulting in cavities along sidewalls of the STI regions 122, as illustrated. In other embodiments, a lateral dimension of each of the first backside contact trenches 156 is less than a lateral dimension of each of the STI regions 122 and no cavities form along sidewalls of the STI regions 122.

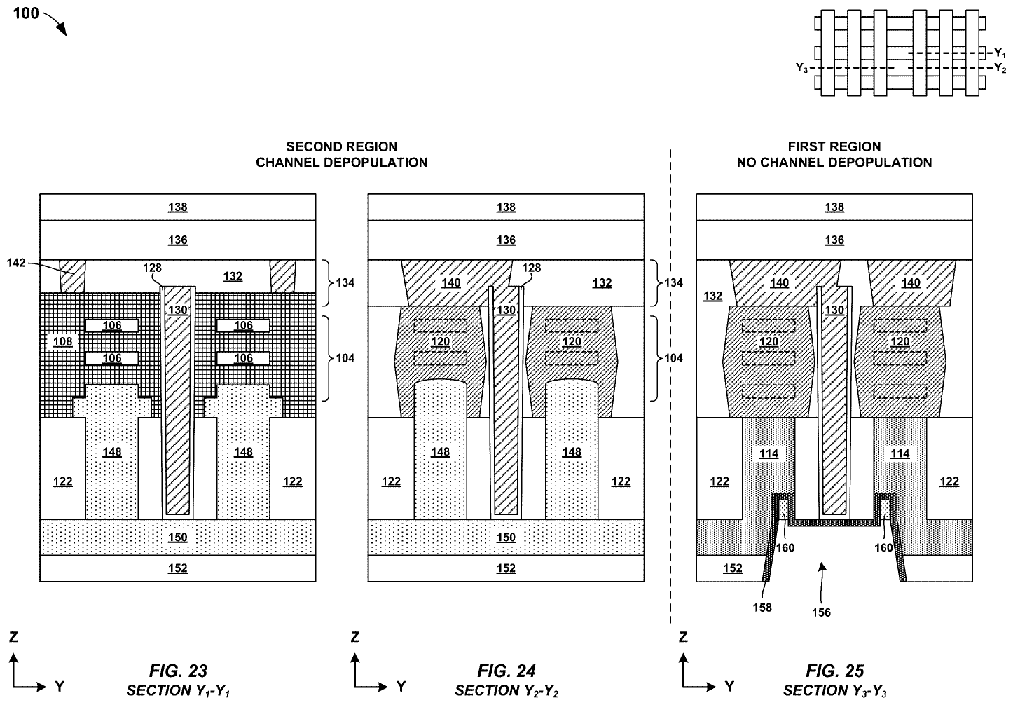

Referring now to FIGS. 23, 24, and 25, the structure 100 is shown after forming a dielectric trench liner 158 a dielectric fill 160 and according to an embodiment of the invention. FIG. 23 depicts a cross-sectional view of the structure 100 taken along line Y₁-Y₁, FIG. 24 depicts a cross-sectional view of the structure 100 taken along line Y₂-Y₂, and FIG. 25 depicts a cross-sectional view of the structure 100 taken along line Y₃-Y₃.

First, the second mask 154 is removed according to known techniques. In an embodiment, the second mask 154 is removed using known techniques, such as, for example, ashing.

Next, the dielectric trench liner 158 is formed across the backside of the structure 100 according to known techniques. Specifically, a dielectric liner material is conformally deposited across the backside of the structure 100 including surfaces exposed within the first backside contact trenches 156, as illustrated. In some embodiments, for example, the dielectric trench liner 158 may be composed of low-k materials, such as, for example, SiN, SiBCN, SiOCN, SiOC, or other combinations thereof. According to embodiments of the present invention, the dielectric trench liner 158 provides etch selectivity during backside processing. More specifically, the dielectric trench liner 158 must be made from a material which permits removal of subsequent masking materials, as described below.

Finally, the dielectric fill 160 is formed across the backside of the structure 100 according to known techniques. Specifically, a dielectric fill material is blanket deposited across the backside of the structure 100 including within the first backside contact trenches 156, as illustrated. In some embodiments, for example, the dielectric fill 160 may be composed of low-k materials, such as, for example, oxides. After depositing, the dielectric fill 160 is recessed to according to known technique. Specifically, the dielectric fill 160 is recessed until at least the horizontal surface of the dielectric trench liner 158 becomes exposed, as illustrated. As illustrated, the dielectric fill 160 fills the cavities along sidewalls of the STI regions 122 in embodiments where a lateral dimension of each of the first backside contact trenches 156 is greater than a lateral dimension of each of the STI regions 122. the dielectric fill 160 ensures completed isolation between the top semiconductor layer 114 and subsequently formed backside contact structures.

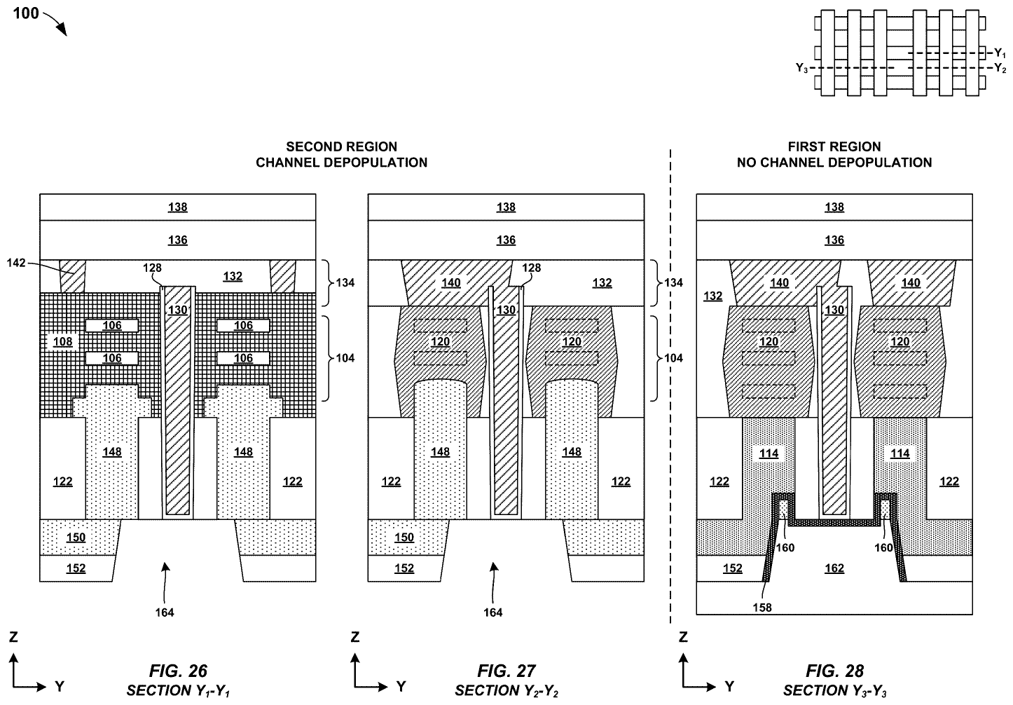

Referring now to FIGS. 26, 27, and 28, the structure 100 is shown after forming a third mask 162 and second backside contact trenches 164 according to an embodiment of the invention. FIG. 26 depicts a cross-sectional view of the structure 100 taken along line Y₁-Y₁, FIG. 27 depicts a cross-sectional view of the structure 100 taken along line Y₂-Y₂, and FIG. 28 depicts a cross-sectional view of the structure 100 taken along line Y₃-Y₃.

The third mask 162 is deposited and subsequently patterned to expose certain backside portions of the structure 100 according to known techniques. The third mask 162 can be an organic planarization layer (OPL) or a layer of material that is capable of being planarized or etched by known techniques. In an embodiment, for example, the third mask 162 can be an amorphous carbon layer able to withstand subsequent processing temperatures. The third mask 162 can preferably have a thickness sufficient to cover existing structures. After depositing the third mask 162, a dry etching technique is applied to pattern the third mask 162 according to known techniques. The third mask 162 is patterned to expose backside surfaces in the second region (see FIGS. 26 and 27) and remains across backside surfaces of the first region (see FIG. 28). Specifically, after patterning the third mask 162, portions of the hard mask layer 152 will be exposed in the second region and other portions of the hard mask layer 152 will remain covered in the first region.

Next, the hard mask layer 152, exposed in the second region, is patterned and the second backside contact trenches 164 are formed according to known techniques. Specifically, known techniques are used to pattern the exposed portions of the hard mask layer 152 in the second region according to known techniques. Next, according to an exemplary embodiment, RIE is used to transfer the hard mask pattern into the backside dielectric layer 150 according to known techniques and as illustrated.

According to embodiments of the present invention, second backside contact trenches 164 are generally aligned with one or more of the contact fill 130, as illustrated. According to the disclosed embodiments, portions of the backside dielectric layer 150 in the second region will be removed selective to the STI regions 122 and the contact liner 128. Unlike the first backside contact trenches 156, etching shall generally stop once bottommost surfaces of the STI regions 122 and the contact liner 128 are exposed, as illustrated; however, some over etching has no negative consequence. According to an embodiment, both the STI regions 122 and the backside channel plugs 148 are made from oxide and will provide a suitable etch stop.

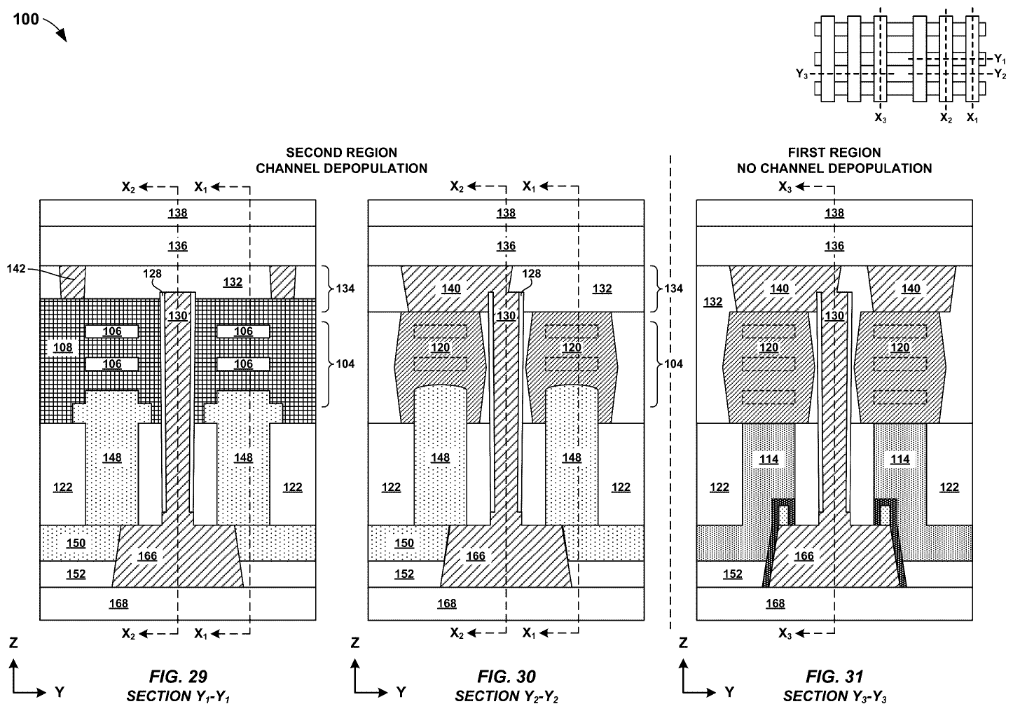

Referring now to FIGS. 29, 30, 31, 32, 33, and 34 the structure 100 is shown after forming backside contact structures 166 and backside wiring layers 168 according to an embodiment of the invention. FIG. 29 depicts a cross-sectional view of the structure 100 taken along line Y₁-Y₁, FIG. 30 depicts a cross-sectional view of the structure 100 taken along line Y₂-Y₂, FIG. 31 depicts a cross-sectional view of the structure 100 taken along line Y₃-Y₃, FIG. 32 depicts a cross-sectional view of the structure 100 taken along line X₁-X₁, FIG. 33 depicts a cross-sectional view of the structure 100 taken along line X₂-X₂, and FIG. 34 depicts a cross-sectional view of the structure 100 taken along line X₃-X₃.

First, the third mask 162 is removed according to known techniques. In an embodiment, the third mask 162 is removed using known techniques, such as, for example, ashing. After removing the third mask 162, the dielectric trench liner 158 is exposed in the first region.

Next, portions of the contact liner 128 and the dielectric trench liner 158 are removed to expose the contact fill 130 according to known techniques. For example, known directional or anisotropic etching techniques are used to remove portions of the and the dielectric trench liner 158 exposed in the first region, and portions of the contact liner 128 exposed in both the first region and the second region. Etching shall continue until the contact fill 130 is exposed.

The first backside contact trenches 156 and the second backside contact trenches 164 are then filled with a conductive material to form the backside contact structures 166 according to known techniques. The backside contact structures 166 may include any suitable conductive material, such as, for example, copper, ruthenium, aluminum, tungsten, cobalt, or alloys thereof. After filling, excess conductive material can be polished using known techniques until bottommost surfaces of the backside contact structures 166 are flush, or substantially flush, with bottommost surfaces of the hard mask layer 152, as illustrated. As previously indicated, the backside contact structures 166 must be isolated from the top semiconductor layer 114 to prevent current leakage to substrate, and the dielectric trench liner 158 and the dielectric fill 160 provide that isolation.

After forming the backside contact structures 166, the backside wiring layers 168 are subsequently formed according to known techniques. The backside wiring layers 168 typically include at least backside power rails and a backside power delivery network.

According to the embodiment illustrated in FIGS. FIGS. 29-34, the transistor structures represented by the structure 100 have some distinctive notable features. For instance, the nanosheet stacks in the second region have fewer nanosheet channels than the nanosheet stacks in the first region. Precise control of the number of channels in the different regions is a way to enable low power and high-performance device cointegration.

It is noted, the backside contact structures 166 are formed in direct electrical contact with the contact fill 130 of the gate cut contact structures, as illustrated. Together the backside contact structures 166 and the gate cut contact structures form an electrical path from the backside to the source drain contacts 140 on the frontside through, on in, a gate cut region, also as illustrated. Furthermore, the contact liner 128 electrically insulates the electrical path, specifically, the contact fill 130 from surrounding structures, for example, adjacent source drain regions 120. Due to the fabrication order, a portion of the contact liner 128 is sandwiched between the contact fill 130 and the source drain contacts 140. Said differently, top surfaces of both the contact liner 128 and the contact fill 130 are above bottom surfaces of the source drain contacts 140. Turning to the backside, the backside contact structures 166 in the first region are surrounded by the dielectric trench liner 158. Meanwhile, the backside contact structures 166 in the second region are not surrounded by the dielectric trench liner 158. Additionally, the dielectric fill 160 is present directly above and contacting the backside contact structures 166 in the first region, but not the backside contact structures 166 in the second region.

With continued reference to FIGS. 29-34, and according to an embodiment, the structure 100 includes a first stack of semiconducting layers in a first region, a second stack of semiconducting layers in a second region, where the second stack of semiconducting layers in the second region has at least one fewer layer than the first stack of semiconducting layers in the first region, a backside channel plug directly beneath the first stack of semiconducting layers in the first region, and a gate cut contact structure extending between a backside contact structure and a source drain contact on a frontside.

With continued reference to FIGS. 29-34, and according to an embodiment, the backside channel plug extends laterally perpendicular to a gate, and is directly beneath adjacent source drain regions.

With continued reference to FIGS. 29-34, and according to an embodiment, the structure further includes a first source drain region in the first region; and

With continued reference to FIGS. 29-34, and according to an embodiment, a bottom surface of the second source drain region in the second region is above a bottom surface of the first source drain region in the first region.

With continued reference to FIGS. 29-34, and according to an embodiment, a portion of the second source drain region partially surrounds sidewalls of a top portion of the backside channel plug.

With continued reference to FIGS. 29-34, and according to an embodiment, the backside channel plug is self-aligned to shallow trench isolation regions.

With continued reference to FIGS. 29-34, and according to an embodiment, the backside channel plug comprises a compressive dielectric material, a tensile dielectric material, or some combination thereof.

With continued reference to FIGS. 29-34, and according to an embodiment, the backside channel plug comprises two or more dielectric materials.

With continued reference to FIGS. 29-34, and according to an embodiment, the structure 100 includes a first stack of semiconducting layers in a first region, a second stack of semiconducting layers in a second region, where the second stack of semiconducting layers in the second region has at least one fewer layer than the first stack of semiconducting layers in the first region, a backside channel plug directly beneath the first stack of semiconducting layers in the first region, and gate cut contact structures extending between backside contact structures and source drain contacts on a frontside, where one of the backside source drain contact structures in the second region is surrounded by a dielectric trench liner and a dielectric fill.

With continued reference to FIGS. 29-34, and according to an embodiment, the structure 100 includes a first gate surrounding at least one layer of a first stack of semiconducting layers in a first region, a second gate surrounding at least one layer of a second stack of semiconducting layers in a second region, wherein the second stack of semiconducting layers in the second region has at least one fewer layer than the first stack of semiconducting layers in the first region, a backside channel plug directly beneath the first stack of semiconducting layers in the first region, wherein a top portion of the backside channel plug is surrounded on at least two sides by the second gate in the second region, and a gate cut contact structure extending between a backside contact structure and a source drain contact on a frontside.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a first stack of semiconducting layers in a first region;
a second stack of semiconducting layers in a second region, wherein the second stack of semiconducting layers in the second region has at least one fewer layer than the first stack of semiconducting layers in the first region;
a backside channel plug directly beneath the first stack of semiconducting layers in the first region; and
a gate cut contact structure extending between a backside contact structure and a source drain contact on a frontside.

2. The semiconductor structure according to claim 1, wherein the backside channel plug extends laterally perpendicular to a gate, and is directly beneath adjacent source drain regions.

3. The semiconductor structure according to claim 1, further comprising:
a first source drain region in the first region; and
a second source drain region in a second region, wherein a bottom surface of the second source drain region in the second region is above a bottom surface of the first source drain region in the first region.

4. The semiconductor structure according to claim 3, wherein a portion of the second source drain region partially surrounds sidewalls of a top portion of the backside channel plug.

5. The semiconductor structure according to claim 1, wherein the backside channel plug is self-aligned to shallow trench isolation regions.

6. The semiconductor structure according to claim 1, wherein the backside channel plug comprises a compressive dielectric material, a tensile dielectric material, or some combination thereof.

7. The semiconductor structure according to claim 1, wherein the backside channel plug comprises two or more dielectric materials.

8. A semiconductor structure comprising:
a first stack of semiconducting layers in a first region;
a second stack of semiconducting layers in a second region, wherein the second stack of semiconducting layers in the second region has at least one fewer layer than the first stack of semiconducting layers in the first region;
a backside channel plug directly beneath the first stack of semiconducting layers in the first region; and
gate cut contact structures extending between backside contact structures and source drain contacts on a frontside, wherein one of the backside contact structures in the second region is surrounded by a dielectric trench liner and a dielectric fill.

9. The semiconductor structure according to claim 8, wherein the backside channel plug extends laterally perpendicular to a gate, and is directly beneath adjacent source drain regions.

10. The semiconductor structure according to claim 8, further comprising:
a first source drain region in the first region; and
a second source drain region in a second region, wherein a bottom surface of the second source drain region in the second region is above a bottom surface of the first source drain region in the first region.

11. The semiconductor structure according to claim 10, wherein a portion of the second source drain region partially surrounds sidewalls of a top portion of the backside channel plug.

12. The semiconductor structure according to claim 8, wherein the backside channel plug is self-aligned to shallow trench isolation regions.

13. The semiconductor structure according to claim 8, wherein the backside channel plug comprises a compressive dielectric material, a tensile dielectric material, or some combination thereof.

14. The semiconductor structure according to claim 8, wherein the backside channel plug comprises two or more dielectric materials.

15. A semiconductor structure comprising:
a first gate surrounding at least one layer of a first stack of semiconducting layers in a first region;
a second gate surrounding at least one layer of a second stack of semiconducting layers in a second region, wherein the second stack of semiconducting layers in the second region has at least one fewer layer than the first stack of semiconducting layers in the first region;
a backside channel plug directly beneath the first stack of semiconducting layers in the first region, wherein a top portion of the backside channel plug is surrounded on at least two sides by the second gate in the second region; and
a gate cut contact structure extending between a backside contact structure and a source drain contact on a frontside.

16. The semiconductor structure according to claim 15, wherein the backside channel plug extends laterally perpendicular to a gate, and is directly beneath adjacent source drain regions.

17. The semiconductor structure according to claim 15, further comprising:
a first source drain region in the first region; and
a second source drain region in a second region, wherein a bottom surface of the second source drain region in the second region is above a bottom surface of the first source drain region in the first region.

18. The semiconductor structure according to claim 17, wherein a portion of the second source drain region partially surrounds sidewalls of a top portion of the backside channel plug.

19. The semiconductor structure according to claim 15, wherein the backside channel plug is self-aligned to shallow trench isolation regions.

20. The semiconductor structure according to claim 15, wherein the backside channel plug comprises a compressive dielectric material, a tensile dielectric material, or some combination thereof.
